(19) United States
(12) Patent Application Publication
(10) Pub. No.: US 2025/0197195 A1
(43) Pub. Date: Jun. 19, 2025

(54) MEMS DEVICE AND MANUFACTURING METHOD THEREOF

(71) Applicant: AAC Technologies Pte. Ltd., Singapore (SG)

(72) Inventors: Veronica Tan, Singapore (SG); Zhan Zhan, Shenzhen (CN); Houming Chong, Johor (MY); Zaixiang Pua, Singapore (SG); Kahkeen Lai, Singapore (SG)

(21) Appl. No.: 18/539,244

(22) Filed: Dec. 13, 2023

(51) Int. Cl. B81B 7/00; B81C 1/00

(52) U.S. Cl. CPC B81B 7/0022; B81C 1/00269; B81B 2203/033; B81B 2203/04; B81C 2201/0132; B81C 2201/0154; B81C 2203/0109

(57) ABSTRACT

The MEMS device includes a cap sheet defining a recess, and a device sheet bonded with the cap sheet and defining a functional cavity directly facing the recess. The cap sheet includes a substrate having a first surface facing the device sheet, a ground structure and a first metal layer disposed on a portion of the first surface outside the recess, and the ground structure disposed along perimeter of an area where the first metal layer located. The device sheet includes a substrate, a structure layer and a second metal layer sequentially stacked. The structure layer includes a first portion located in the functional cavity and a second portion surrounding the first portion, and the second metal layer is located on the second portion. By the first and second metal layer, the cap sheet is bonded with the device sheet, and all electrodes of the MEMS device are electrically connected.

### TECHNIC FIELD

The various embodiments described in this document relate in general to the field of semiconductor manufacturing, and more specifically to a micro electro mechanical system (MEMS) device and a manufacturing method thereof.

### BACKGROUND

Electronic devices, such as commercial products (for example, True Wireless Stereo (TWS), wearable, phone, etc.), and higher-end products (for example, automotive), often include MEMS devices. MEMS devices such as inertia sensors, may, for example, be used to form accelerometers, gyroscopes and other types of sensors.

In recent years, technology for manufacturing MEMS devices having a three-dimensional structure in which a plurality of device die or device wafers are integrated in their thickness direction thereof has been developed primarily, for the purpose of further increasing the density of MEMS devices. When the plurality of Device Die involved at least 2 or more electrodes, eg. a Top wafer and a Bottom wafer, it is important to ensure all electrodes are grounded on the same potential. Without proper grounding, one of the electrodes will be electrically floating and induced unwanted charge accumulation within the electrodes. This phenomenon translates to higher resistance and larger parasitic capacitance for an electronic device, resulting in slower initiation response time and poorer signal to noise ratio (SNR).

Therefore, it is desired to provide a proper ground structure for MEMS devices.

### SUMMARY

According to one aspect of the present disclosure, a MEMS device is provided. The MEMS device includes a cap sheet defining a recess, and a device sheet bonded with the cap sheet and defining a functional cavity directly facing the recess. The cap sheet includes a substrate and a first metal layer, the substrate has a first surface facing the device sheet, the recess is defined on the first surface and the first metal layer is disposed on a portion of the first surface outside the recess. The device sheet includes a substrate, a structure layer and a second metal layer sequentially stacked, the structure layer includes a first portion, in which structures for achieving mechanical functionality are formed, located in the functional cavity and a second portion surrounding the first portion, and the second metal layer is located on the second portion. Each of the cap sheet and the device sheet includes at least one electrode, the cap sheet is bonded with the device sheet via the first metal layer and the second metal layer, and all electrodes are electrically connected via the first metal layer and the second metal layer bonded with each other. The cap sheet further includes a ground structure on the portion of the first surface outside the recess, and disposed along perimeter of a bonding area where the first metal layer located.

In some embodiments, the ground structure is disposed on both sides or either side of the bonding area.

In some embodiments, the bonding area is ring-shaped, and the ground structure is disposed along one or both of an outer side and an inner side of the bonding area.

In some embodiments, the ground structure is a complete loop trench, or is a single or multiple short trenches.

In some embodiments, the first metal layer covers the ground structure either fully or partially.

According to another aspect of the present disclosure, a method for manufacturing the MEMS device as described above is provided. The method includes forming the cap sheet, forming the device sheet, and bonding the cap sheet and the device sheet. Forming the cap sheet includes: providing a first substrate; forming an oxide layer on a first surface of the first substrate; patterning the oxide layer to form a grounding structure and to reserve targeted bonding area, the grounding structure being disposed along perimeter of the targeted bonding area; forming a first metal layer over the oxide layer at the target bonding area and in the grounding structure; and removing portions of the oxide layer and the first substrate to form the recess, so that the first metal layer and the grounding structure are disposed on the portion of the first surface outside the recess. Forming the device sheet includes: providing a second substrate; and forming the structure layer and the second metal layer on the second substrate, so that the structure layer includes a first portion, in which structures for achieving mechanical functionality are formed, located in the functional cavity and a second portion surrounding the first portion, and the second metal layer is located on the second portion. Bonding the cap sheet and the device sheet includes: performing a bonding process on the first metal layer and the second metal layer, so that the cap sheet is bonded with the device sheet via the first metal layer and the second metal layer, and all electrodes are electrically connected via the first metal layer and the second metal layer bonded with each other.

In some embodiments, patterning the oxide layer to form the grounding structure and to reserve the targeted bonding area includes disposing the ground structure on both sides or either side of the bonding area.

In some embodiments, patterning the oxide layer to form the grounding structure and to reserve the targeted bonding area includes disposing the targeted bonding area as ring-shaped, and disposing the ground structure along one or both of an outer side and an inner side of the targeted bonding area.

In some embodiments, patterning the oxide layer to form the grounding structure and to reserve the targeted bonding area includes disposing the ground structure as a complete loop trench, or as a single or multiple short trenches.

In some embodiments, in performing a bonding process on the first metal layer and the second metal layer, the first metal layer is squeezed out to flow into the ground structure to make the first metal layer cover the ground structure either fully or partially.

### BRIEF DESCRIPTION OF THE DRAWINGS

The present embodiments are illustrated by way of example and not limitation in the figures of the accompanying drawings, in which like references may indicate similar elements.

FIG. 1A is a schematic diagram for illustrating a cross-sectional view of a MEMS device in accordance with an embodiment of the present disclosure.

FIG. 1B is a schematic diagram for illustrating an exemplary relationship between an enclosed cavity and a bonding ring in accordance with an embodiment of the present disclosure.

FIGS. 2A and 2B are schematic diagrams for illustrating an isolated island structure created as a ground structure.

FIGS. 3A and 3B are schematic diagrams for illustrating another isolated island structure created as a ground structure.

FIGS. 4A, 4B and 4C are schematic diagrams for illustrating a ground structure embedded within a bonding ring.

FIG. 4D is a local scanning electron microscope (FA SEM) diagram at ground structure.

FIG. 5A is a schematic diagram for illustrating a cross-sectional view of another MEMS device in accordance with an embodiment of the present disclosure.

FIG. 5B is a schematic diagram showing an enlarged view of the ground structure 507 of FIG. 5A.

FIG. 6A is a schematic diagram for illustrating a cross-sectional view of a further MEMS device in accordance with an embodiment of the present disclosure.

FIG. 6B is a schematic diagram showing an enlarged view of the ground structure 607 of FIG. 6A.

FIG. 7A is a schematic diagram for illustrating a cross-sectional view of a still another MEMS device in accordance with an embodiment of the present disclosure.

FIG. 7B is a schematic diagram showing an enlarged view of the ground structure 707 of FIG. 7A.

FIGS. 8A˜8D illustrate intermediate steps of fabricating a cap sheet of a MEMS device in accordance with an embodiment.

FIG. 9A is a schematic diagram for illustrating an exemplary layout of the grounding loop.

FIG. 9B is a schematic diagram for illustrating another exemplary layout of the grounding loop.

FIG. 10A is a schematic diagram for illustrating a cross sectional view of bonding area on left side of a cap sheet in accordance with an embodiment.

FIG. 10B is a schematic diagram for illustrating another cross sectional view of bonding area on left side of a cap sheet in accordance with an embodiment.

FIG. 10C is a schematic diagram for illustrating a further cross sectional view of bonding area on left side of a cap sheet in accordance with an embodiment.

FIG. 11 is a schematic diagram for illustrating a cross sectional view of a device sheet in accordance with an embodiment.

FIG. 12 is a schematic diagram for illustrating a structure layer of a MEMS gyroscope.

FIG. 13 is another local scanning electron microscope (FA SEM) diagram at ground structure.

FIG. 14 is a flow chat of a method for manufacturing a MEMS device in accordance with an embodiment.

### DETAILED DESCRIPTION OF THE EMBODIMENTS

This specification discloses one or more embodiments that incorporate the features of this disclosure. The disclosed embodiment(s) merely exemplify the disclosure. The scope of the disclosure is not limited to the disclosed embodiment(s). The disclosure is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Terms used in embodiments of the present disclosure are for the purpose of describing specific embodiments only and are not intended to limit the present disclosure. Singular forms “an”, “said”, and “the” as used in embodiments of the present disclosure and in the appended claims are also intended to include a plurality of forms, unless the context clearly dictates otherwise.

It shall be understood that the term “and/or” used herein is merely an association relationship that describes an associated object, indicating that there can be three relationships. For example, the expression “A and/or B” may include three cases: A exists alone, A and B exist at the same time, and B exists alone. In addition, the character “/” herein generally indicates that related objects are a kind of “or” relationship.

It is to be noted that the orientation words “up”, “down”, “left”, “right”, and the like described in the embodiments of the present disclosure are described from the angles shown in the drawings and should not be understood as limiting the embodiments of the present disclosure. Furthermore, in the context, it is to be understood that when a component is referred to as being connected “above/up” or “below/lower” of another component, the component can not only be directly connected to the “above/up” or “below/lower” of the another component, but can also be indirectly connected to the “above/up” or “below/lower” of the another component through a middle component.

Micro-electro-mechanical system (MEMS) devices refer to high-tech devices with a size of several millimeters or even smaller, and a size of an internal structure of this device is generally on the micron scale or even nanometer scale. The MEMS device may include a plurality of elements (e.g., movable elements) for achieving mechanical functionality. In addition, the MEMS devices may include MEMS acoustic sensors, MEMS pressure sensors, and MEMS inertial sensors, and so on. The MEMS inertial sensors generally include a MEMS accelerometer and a MEMS gyroscope.

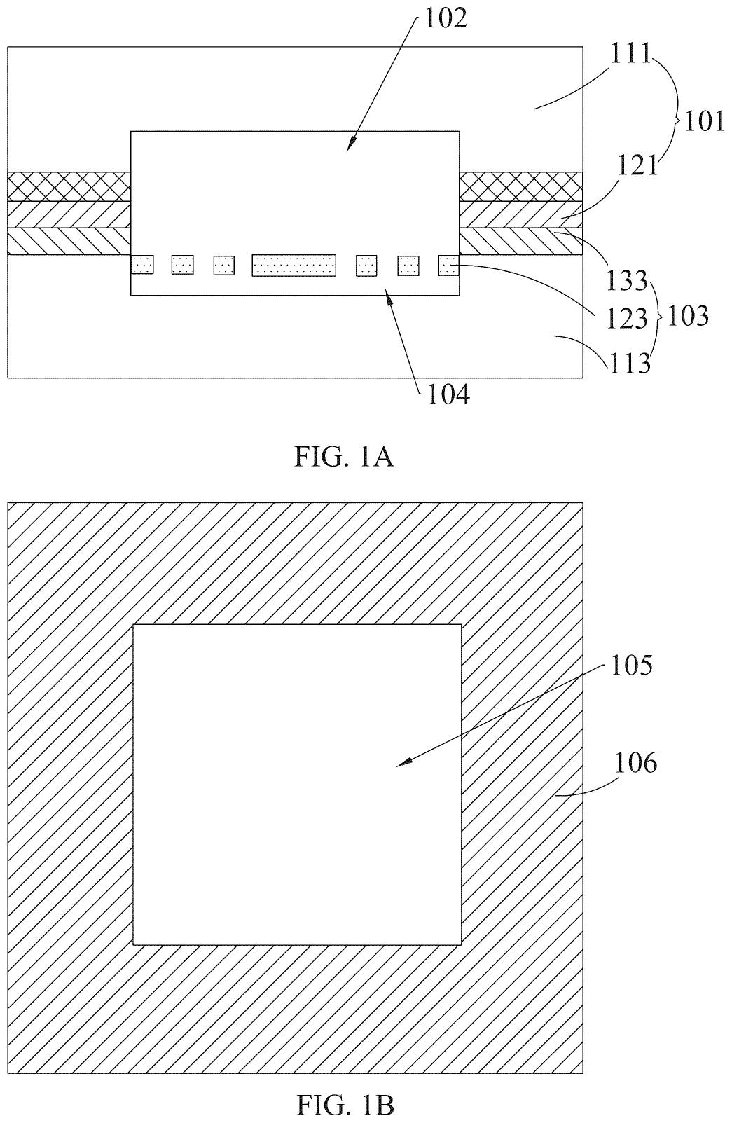

FIG. 1A is a schematic diagram for illustrating a cross-sectional view of a MEMS device in accordance with an embodiment of the present disclosure. The MEMS device includes a cap sheet 101 and a device sheet 103. Suitable bonding techniques such as fusion bonding, eutectic bonding and the like may be employed to bond the cap sheet 101 and the device sheet 103 together.

The cap sheet 101 may include a substrate 111. In accordance with an embodiment, the substrate 111 of the cap sheet 101 may be formed of silicon. Alternatively, the substrate 111 of the cap sheet 101 may be formed of other semiconductor materials including silicon germanium (SiGe), silicon carbide and the like.

The substrate 111 has a first surface facing the device sheet 103. The cap sheet 101 defines a recess 102 on the first surface and includes a first metal layer 121 disposed on a portion of the first surface outside the recess 102.

The device sheet 103 may include a substrate 113. In accordance with an embodiment, the substrate 113 of the device sheet 103 may have similar materials as the substrate 111 of the cap sheet 101. However, the substrates of the cap sheet 101 and the device sheet 103 are not necessary to be the same material.

The device sheet 103 may further include a structure layer 123 and a second metal layer 133 sequentially stacked. The device sheet 103 defines a functional cavity 104 directly facing the recess 102. The structure layer 123 includes a first portion, in which structures for achieving mechanical functionality are formed, located in the functional cavity 104 and a second portion surrounding the first portion. The second metal layer 133 is located on the second portion.

Since the MEMS device needs to be operated in a sealed environment, the cap sheet 101 is bonded with the device sheet 103 via the first metal layer 121 and the second metal layer 133, so that the corresponding movable elements (or the structures for achieving mechanical functionality) of the MEMS device are sealed in the enclosed cavity 105 including the recess 102 and the functional cavity 104 defined by the cap sheet 101 and the device sheet 103.

For the sake of illustration, an area where the first metal layer 121 and the second metal layer 133 are located is called as a bonding area 106. The bonding area 106 may be in any morphologies as needed. For example, the bonding area 106 may be a bonding ring surrounding the enclosed cavity 105. FIG. 1B is a schematic diagram for illustrating an exemplary relationship between an enclosed cavity 105 and a bonding ring 106 in accordance with an embodiment of the present disclosure. However, the bonding area is not limited to the example provided herein.

Each of the cap sheet 101 and the device sheet 103 includes at least one electrode. It is important to ensure all electrodes of the MEMS device are grounded on the same potential, because without proper grounding, one of the electrodes will be electrically floating and induced unwanted charge accumulation within the electrodes.

In order to provide proper grounding, the MEMS device includes a ground structure to electrically connect all electrodes. In some cases, an isolated island structure is created as a ground structure.

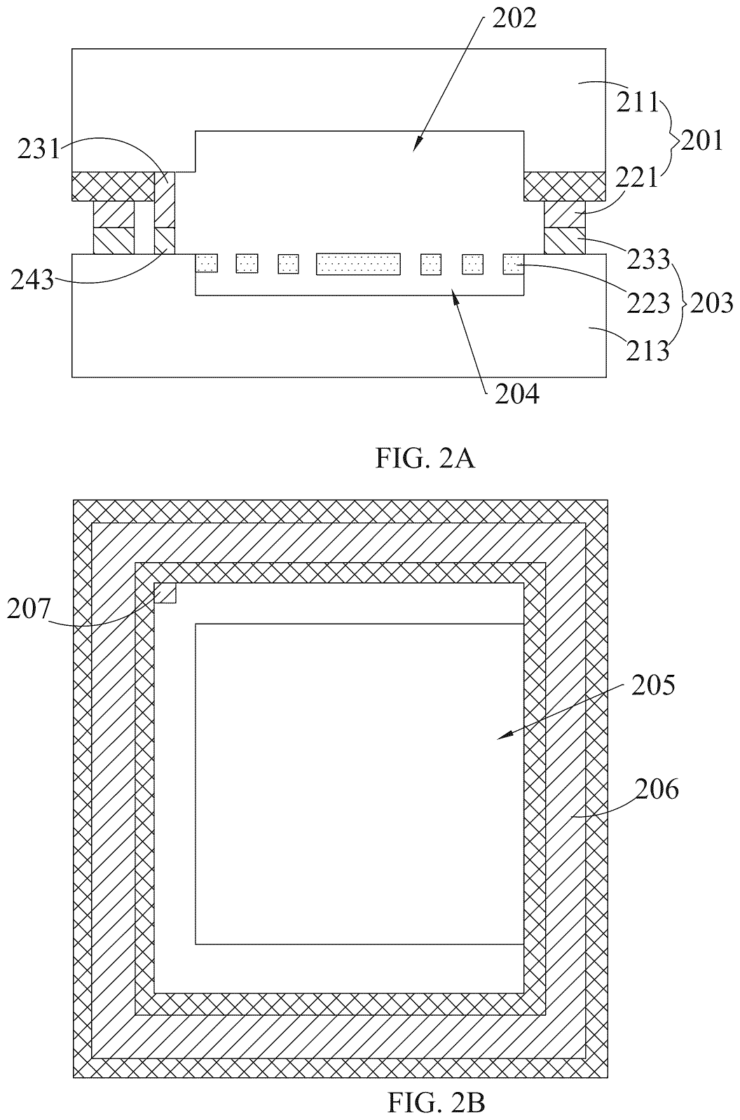

In a design shown in FIGS. 2A and 2B, the structure of the MEMS device is similar to that of the MEMS device as shown in FIGS. 1A and 1B except that a ground structure 207 is formed inside an enclosed cavity 205. Referring to FIGS. 2A and 2B, the MEMS device includes a cap sheet 201 and a device sheet 203. The cap sheet 201 includes a substrate 211, a first metal layer 221 and a first grounding electrode 231, and defines a recess 202. The device sheet 203 includes a substrate 213, a structure layer 223, a second metal layer 233 and a second grounding electrode 243, and defines a functional cavity 204. The first grounding electrode 231 and the second grounding electrode 243 form the ground structure 207. In this way, the ground structure is provided. However, this design takes up unnecessary useful functional space inside the enclosed cavity, reducing active device structure area.

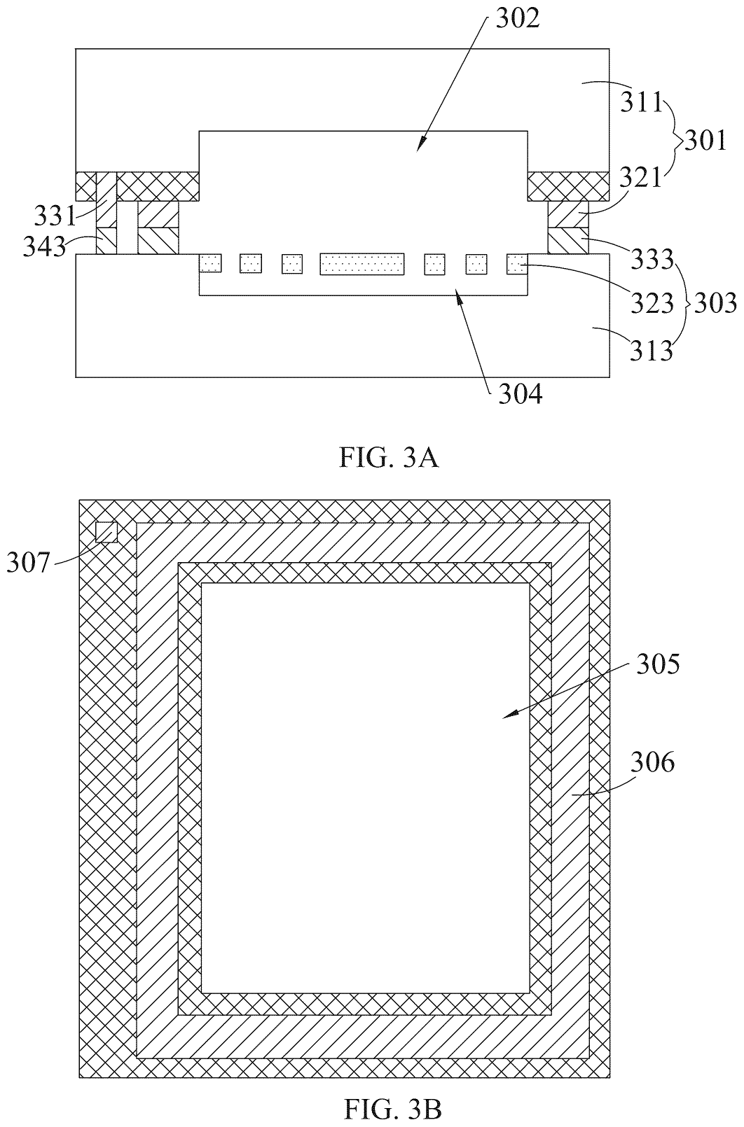

In another design shown in FIGS. 3A and 3B, the structure of the MEMS device is also similar to that of the MEMS device as shown in FIGS. 1A and 1B except that a ground structure 307 is formed outside an enclosed cavity 305. Referring to FIGS. 3A and 3B, the MEMS device includes a cap sheet 301 and a device sheet 303. The cap sheet 301 includes a substrate 311, a first metal layer 321 and a first grounding electrode 331, and defines a recess 302. The device sheet 303 includes a substrate 313, a structure layer 323, a second metal layer 333 and a second grounding electrode 343, and defines a functional cavity 304. The first grounding electrode 331 and the second grounding electrode 343 form the ground structure 307. In this way, the ground structure is provided. However, this design increases the overall die size.

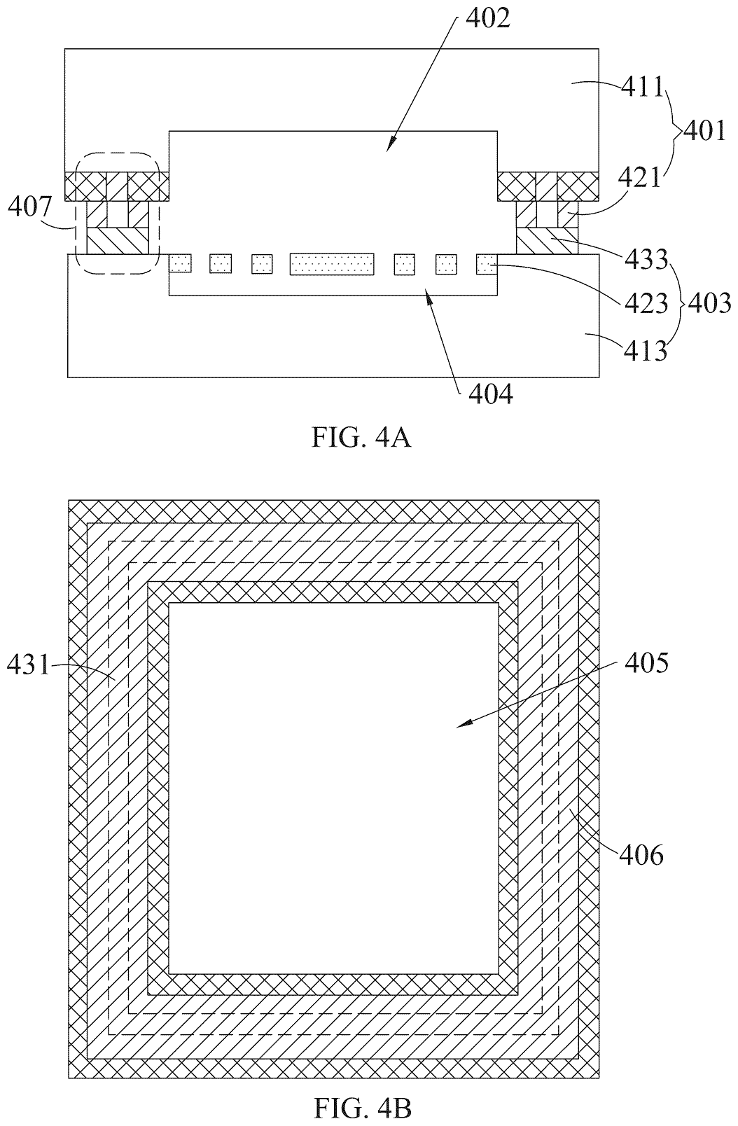

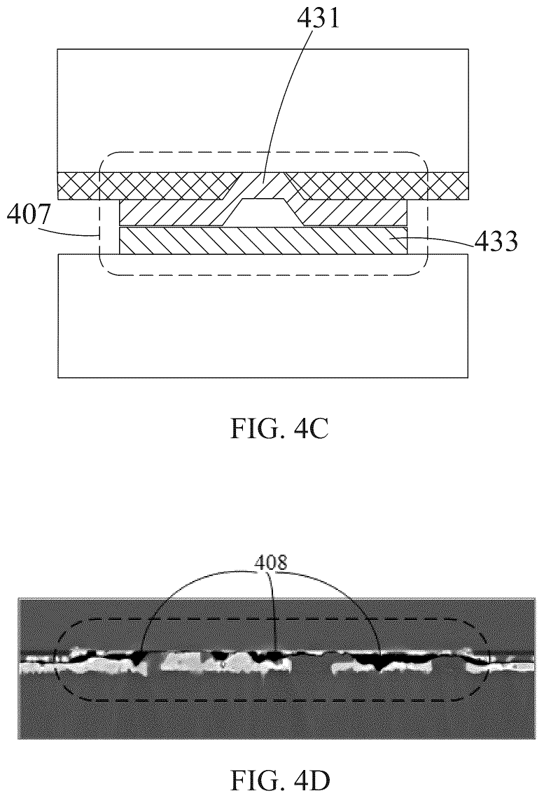

In some other cases, a ground structure is embedded within a bonding ring. In a design shown in FIGS. 4A, 4B and 4C, the structure of the MEMS device is similar to that of the MEMS device as shown in FIGS. 1A and 1B except that a ground structure 407 is embedded within a bonding ring 406. Referring to FIGS. 4A, 4B and 4C, the MEMS device includes a cap sheet 401 and a device sheet 403. The cap sheet 401 includes a substrate 411, a first metal layer 421 and a grounding loop 431, and defines a recess 402. The device sheet 403 includes a substrate 413, a structure layer 423 and a second metal layer 433, and defines a functional cavity 404. The first metal layer 421, the grounding loop 431 and the second metal layer 433 form the ground structure 407. In this way, the ground structure is provided. FIG. 4D is a local scanning electron microscope (FA SEM) diagram at ground structure. It can be seen that the step height at the bonding interface creates unwanted voids 408 at the bonding ring. This weakens the bonding strength and may result in loss of hermeticity over time.

In some embodiments, a MEMS device includes a cap sheet and a device sheet. The cap sheet includes a substrate, a ground structure and a first metal layer, which is formed by depositing first metal material and patterning to form bonding ring structure at targeted bonding area, with the first metal material covering the ground structure either fully or partially. The ground structure is created along the peripheral of the bonding ring structure. The device sheet includes a substrate and a second metal layer, which is bonded with the first metal layer, so as to achieve a sealed environment, and provide proper grounding at the same time.

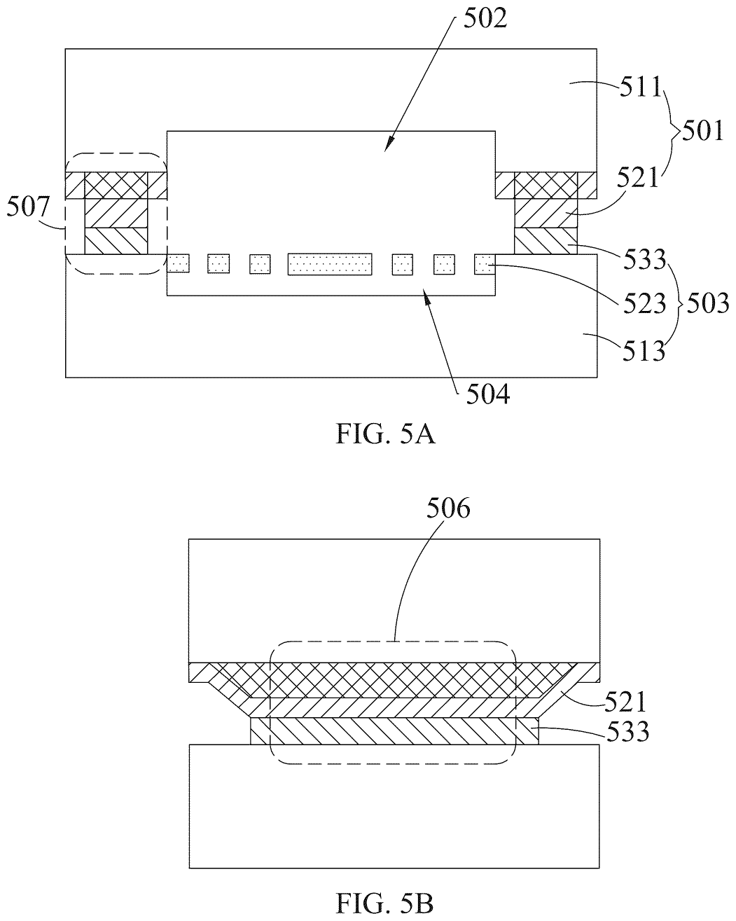

FIG. 5A is a schematic diagram for illustrating a cross-sectional view of another MEMS device in accordance with an embodiment of the present disclosure. FIG. 5B is a schematic diagram showing an enlarged view of the ground structure 507 of FIG. 5A. In a design shown in FIGS. 5A and 5B, the structure of the MEMS device is similar to that of the MEMS device as shown in FIGS. 1A and 1B except that the ground structure 507 is located on both sides of the bonding ring. Referring to FIGS. 5A and 5B, the MEMS device includes a cap sheet 501 and a device sheet 503. The cap sheet 501 includes a substrate 511, a first metal layer 521 and grounding loops, and defines a recess 502. The device sheet 503 includes a substrate 513, a structure layer 523 and a second metal layer 533, and defines a functional cavity 504. The first metal layer 521, the grounding loops and the second metal layer 533 form the ground structure 507. The first metal layer 521 and the second metal layer 533 are located in the bonding area 506, and directly correspond to each other. The grounding loops are disposed along the outer and inner sides of the bonding area 506 respectively.

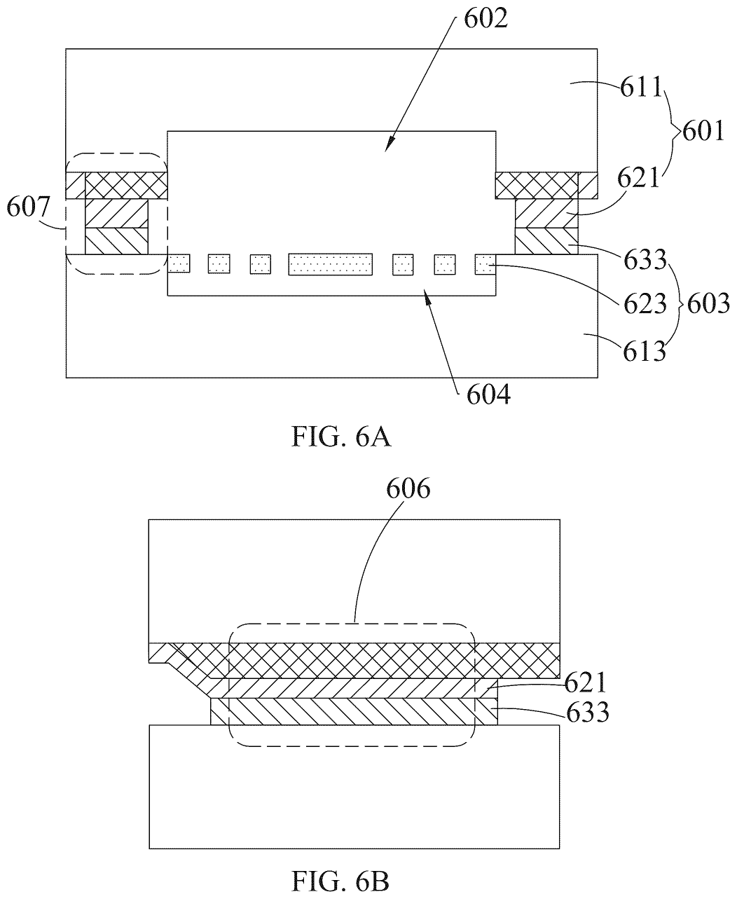

FIG. 6A is a schematic diagram for illustrating a cross-sectional view of a further MEMS device in accordance with an embodiment of the present disclosure. FIG. 6B is a schematic diagram showing an enlarged view of the ground structure 607 of FIG. 6A. In a design shown in FIGS. 6A and 6B, the structure of the MEMS device is similar to that of the MEMS device as shown in FIGS. 1A and 1B except that the ground structure 607 is located on outer side of the bonding ring. Referring to FIGS. 6A and 6B, the MEMS device includes a cap sheet 601 and a device sheet 603. The cap sheet 601 includes a substrate 611, a first metal layer 621 and a grounding loop, and defines a recess 602. The device sheet 603 includes a substrate 613, a structure layer 623 and a second metal layer 633, and defines a functional cavity 604. The first metal layer 621, the grounding loop and the second metal layer 633 form the ground structure 607. The first metal layer 621 and the second metal layer 633 are located in the bonding area 606, and directly correspond to each other. The grounding loop is disposed along the outer side of the bonding area 606.

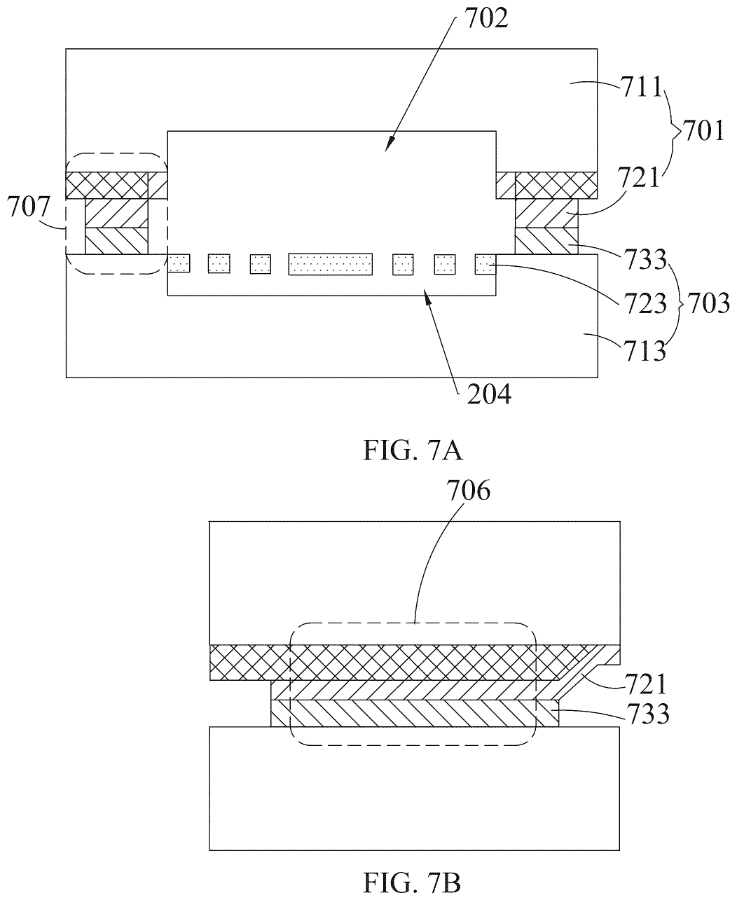

FIG. 7A is a schematic diagram for illustrating a cross-sectional view of a still another MEMS device in accordance with an embodiment of the present disclosure. FIG. 7B is a schematic diagram showing an enlarged view of the ground structure 707 of FIG. 7A. In a design shown in FIGS. 7A and 7B, the structure of the MEMS device is similar to that of the MEMS device as shown in FIGS. 1A and 1B except that the ground structure 707 is located on outer side of the bonding ring. Referring to FIGS. 7A and 7B, the MEMS device includes a cap sheet 701 and a device sheet 703. The cap sheet 701 includes a substrate 711, a first metal layer 721 and a grounding loop, and defines a recess 702. The device sheet 703 includes a substrate 713, a structure layer 723 and a second metal layer 733, and defines a functional cavity 704. The first metal layer 721, the grounding loop and the second metal layer 733 form the ground structure 707. The first metal layer 721 and the second metal layer 733 are located in the bonding area 706, and directly correspond to each other. The grounding loop is disposed along the inner side of the bonding area 706.

In the MEMS device as shown in FIGS. 5A, 5B, 6A, 6B, 7A and 7B, in the bonding process, the cap sheet and the device sheet are bonded together via the first metal layer and the second metal layer, at the same time the grounding of the MEMS device is completed.

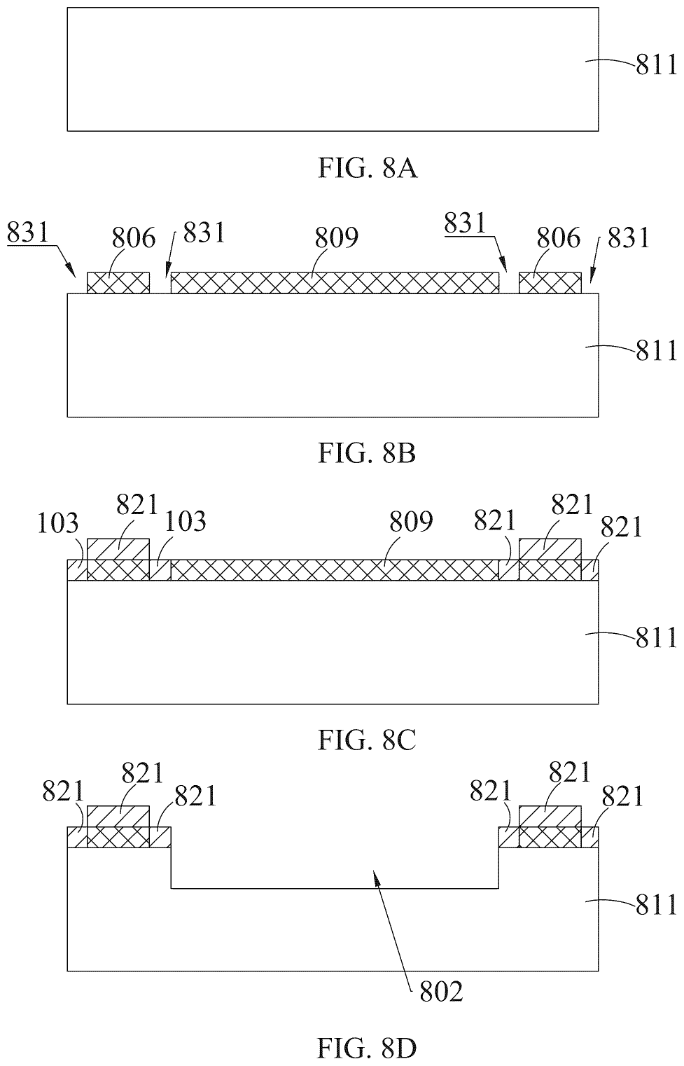

FIGS. 8A˜8D illustrate intermediate steps of fabricating a cap sheet of a MEMS device in accordance with an embodiment. FIG. 8A illustrates a cross-sectional view of a substrate on which other structures of the cap sheet are formed in accordance with an embodiment. The substrate 811 may be formed of silicon, silicon germanium, silicon carbide or the like. Alternatively, the substrate 811 may be a silicon-on-insulator (SOI) substrate. The SOI substrate may comprise a layer of a semiconductor material (e.g., consilicon, germanium and the like) formed over an insulator layer (e.g., buried oxide and the like), which is formed in a silicon substrate. In addition, other substrates that may be used include multi-layered substrates, gradient substrates, hybrid orientation substrates and the like.

FIG. 8B is a cross sectional view of the cap sheet after an oxide deposition process has been applied to a side of the substrate in FIG. 8A in accordance with an embodiment. As shown in FIG. 8B, the oxide layer is formed on a surface of the substrate 811. The oxide deposition may be formed using a deposition process such as CVD or the like.

FIG. 8B further illustrates the patterning of the oxide layer to form grounding loops 831 in the oxide layer. The patterning process may be accomplished by depositing a commonly used mask material (not shown) such as photoresist over the oxide layer. The mask material is then patterned and the oxidde layer is etched in accordance with the pattern to form the grounding loops 831, and to reserve target bonding area 806. As shown in FIG. 8B, the grounding loops 831 are disposed along the outer and inner sides of the bonding area 806 respectively. In addition, the oxide layer, which is labeled as 809, on the center surface of the substrate 811 is a sacrificial oxide layer of the cap sheet. During a releasing process of the cap sheet, the portion 809 helps to reduce the releasing time of the cap sheet.

FIG. 8C illustrates a cross-sectional view of the cap sheet after a metal layer is formed on the oxide layer and in the grounding loops in accordance with an embodiment. A metal layer 821 is deposited over the oxide layer at the target bonding area 806 and in the grounding loops 831. The metal layer may be formed of aluminum, copper, gold, and the like.

FIG. 8D illustrates a cross-sectional view of the cap sheet after a recess is formed in accordance with an embodiment. Portions of the oxide layer 809 and the substrate 811 are removed to define the recess 802. The portion of the oxide layer 809 functions as a sacrificial oxide layer. The sacrificial oxide layer may be subject to a HF vapor etching process. As a result, the portion of the oxide layer 809 is removed. As shown in FIG. 8D, other regions such as the region where the metal layer 821 is located, may be protected.

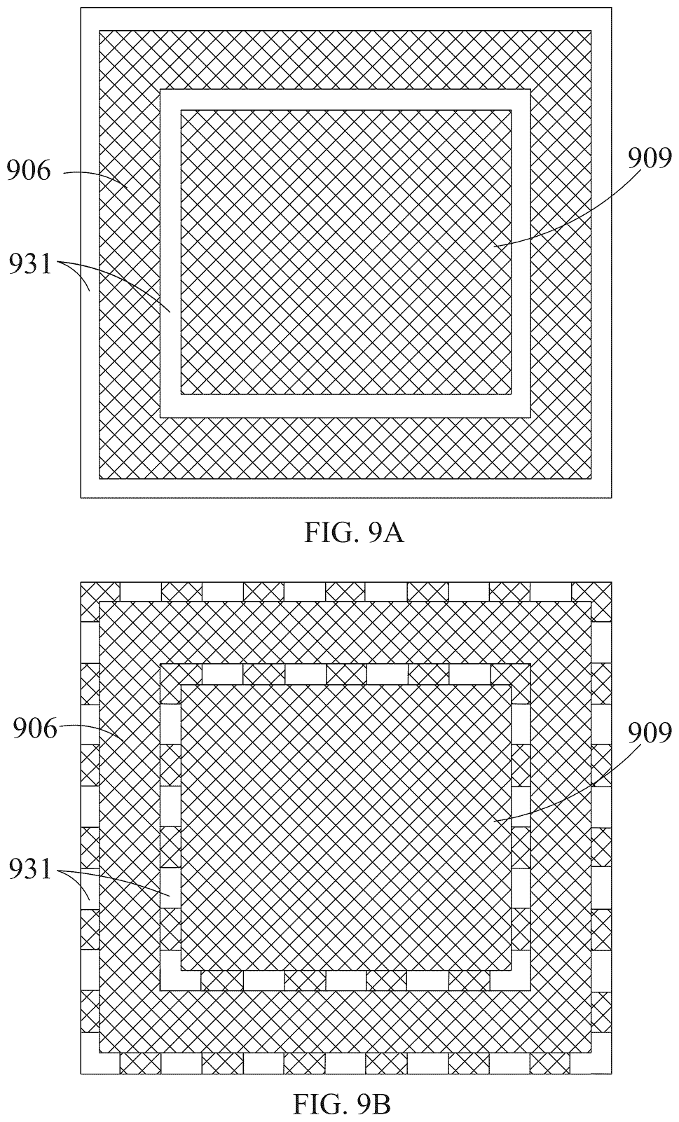

It should be noted that the grounding loop shown in FIG. 8B may be a loop along the outer and/or inner perimeter of targeted bonding area. FIG. 9A is a schematic diagram for illustrating an exemplary layout of the grounding loop. As shown in FIG. 9A, two complete loops 931 of ground structure is disposed along outer and inner sides of the targeted bonding area 906, and the portion of the oxide layer 909 is disposed on the center surface of the substrate. FIG. 9B is a schematic diagram for illustrating another exemplary layout of the grounding loop. As shown in FIG. 9B, two loops 931 with a single or multiple short trenches is disposed along outer and inner sides of the targeted bonding area 906, and the portion of the oxide layer 909 is disposed on the center surface of the substrate. Each trench may be any shape and size, which is not limited herein.

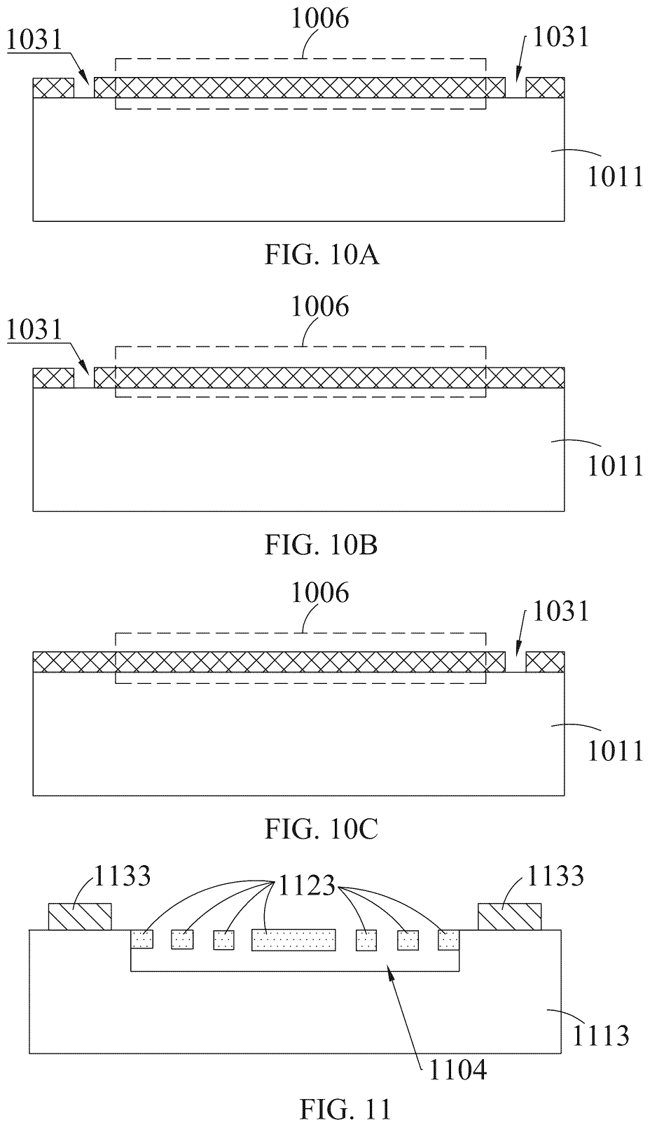

As described above, the ground structure may be created by pattern the oxide on silicon. FIG. 10A is a schematic diagram for illustrating a cross sectional view of bonding area on left side of a cap sheet in accordance with an embodiment. As shown in FIG. 10A, the ground structure 1031 is disposed on both side of the targeted bonding area 1006. FIG. 10B is a schematic diagram for illustrating another cross sectional view of bonding area on left side of a cap sheet in accordance with an embodiment. As shown in FIG. 10B, the ground structure 1031 is disposed on outer side of the targeted bonding area 1006. FIG. 10C is a schematic diagram for illustrating a further cross sectional view of bonding area on left side of a cap sheet in accordance with an embodiment. As shown in FIG. 10C, the ground structure 1031 is disposed on inner side of the targeted bonding area 1006.

FIG. 11 is a schematic diagram for illustrating a cross sectional view of a device sheet in accordance with an embodiment. A substrate 1113 is provided. In accordance with an embodiment, the substrate 1113 may have similar materials as the substrate 811. However, the substrates 1113 and 811 are not necessary to be the same material.

A structure layer 1123 and a second metal layer 1133 are sequentially stacked over the substrate 1113. A functional cavity 1104 is formed. The structure layer 1123 includes a first portion, in which structures for achieving mechanical functionality are formed, located in the functional cavity 1104 and a second portion surrounding the first portion. The second metal layer 1133 is located on the second portion.

After a cap sheet and a device sheet are fabricated, for example, the cap sheet shown in FIG. 8D and the device sheet shown in FIG. 11 are fabricated, the cap sheet is bonded with the device sheet via the first metal layer and the second metal layer to form a MEMS device, such as the MEMS device as shown in FIG. 5A.

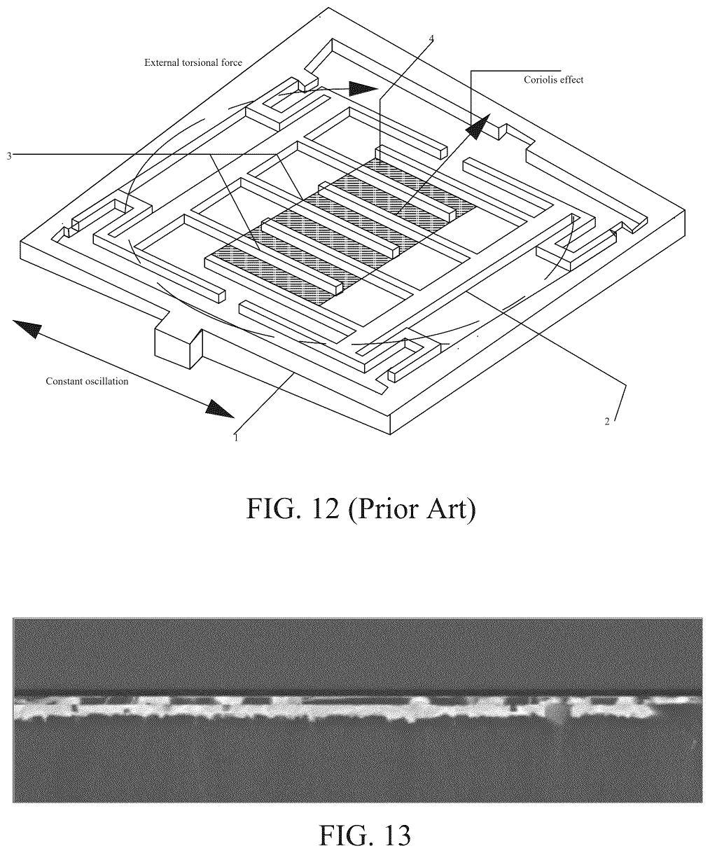

It should be understood that the structure layer involved in the above embodiments may be any structure for achieving mechanical functionality of the MEMS device. FIG. 12 is a schematic diagram for illustrating a structure layer of a MEMS gyroscope. As illustrated in FIG. 12, the MEMS gyroscope includes a drive structure 1 and a detection structure 2. The drive structure 1 is configured to generate drive signals and the detection structure 2 is configured to detect angular velocity of the carrier according to the drive signals generated. The detection structure 2 includes comb-like structures 3. Any existing fabricating process may be employed to form the structure layer. The structure layer is not limited herein, and may be any structure as needed.

As can be seen, according to embodiments of the present disclosure, creating ground structure along the peripheral of the bonding ring structure allows maximal utilisation of the effective device area and cavity area. This facilitates the feasibility for optimal die size reduction. This is especially beneficial for 2 or more electrodes with grounding ability when bonded together as it ensures the whole device is connected at the same potential with minimal space wasted to create repeated ground structure for each electrode. Furthermore, having the ground structure along the outer/inner side of the bonding area allows excessive metal material that are squeezed out during the bonding process to flow into the ground trenches, and not flow towards the device active area or towards the neighbouring active die. In addition, with the ground structure created outside of the effective bonding area, there is no step height differences within the bonding area and the optimal bonding area is retained. This avoid creation of voids along bonding interface. Hence, ensuring the bonding quality and bonding strength is not compromised as shown in FIG. 13. FIG. 13 is another local scanning electron microscope (FA SEM) diagram at the ground structure, such as the regions 506, 606, 706 and 1006 as shown in FIGS. 5B, 6B, 7B, 10A, 10B and 10C, respectively. It can be seen that with the ground structure disposed along peripheral of the bonding ring, no observable voids can be seen at bonding interface of the bonding ring in the FA SEM image.

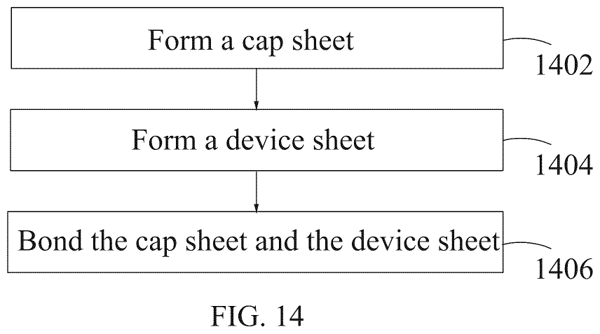

The following will describe a method for manufacturing the MEMS device shown in FIG. 5A. FIG. 14 is a flow chat of a method for manufacturing a MEMS device in accordance with an embodiment.

As illustrated in FIG. 14, the method for manufacturing the MEMS device is provided for manufacturing the MEMS device in foregoing embodiments. The method begins at block 1402.

At block 1402, a cap sheet is formed.

At block 1404, a device sheet is formed.

At block 1406, the cap sheet and the device sheet are bonded.

In some embodiments, the cap sheet is formed as follows. A substrate is provided. An oxide layer is formed on a surface of the substrate and patterned to form a grounding loop and to reserve target bonding area. A metal layer is formed over the oxide layer at the target bonding area and in the grounding loop. Portions of the oxide layer and the substrate are removed to define the recess. It shall be understood that the fabricating procedure of a cap sheet is similar to the procedure as illustrated in FIGS. 8A˜8D, which is not repeat herein.

In some embodiments, the device sheet is formed as follows. A substrate is provided. A structure layer and a second metal layer are sequentially stacked over the substrate. A functional cavity is formed. The structure layer includes a first portion, in which structures for achieving mechanical functionality are formed, located in the functional cavity and a second portion surrounding the first portion. The second metal layer is located on the second portion.

In some embodiments, the cap sheet is bonded with the device sheet via the first metal layer and the second metal layer, so that the corresponding movable elements (or the structures for achieving mechanical functionality) of the MEMS device are sealed in the enclosed cavity including the recess and the functional cavity defined by the cap sheet and the device sheet. The enclosed cavity provides a sealed environment in which the MEMS device needs to be operated.

It should be understood that the MEMS device is fabricated by completing above-mentioned operations in a vacuum environment, thereby drying moisture and/or organic gas in the functional cavity, so as to keep operating performance of the MEMS device at a stable level and improve the operating reliability of the MEMS device and prolong service life of the MEMS device.

This specification discloses one or more embodiments that incorporate the features of this disclosure. The disclosed embodiment(s) merely exemplify the present disclosure. The scope of the present disclosure is not limited to the disclosed embodiment(s). The present disclosure is defined by the claims appended hereto.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A micro electro mechanical system (MEMS) device, comprising:
a cap sheet defining a recess; and
a device sheet bonded with the cap sheet and defining a functional cavity directly facing the recess; wherein
the cap sheet includes a substrate and a first metal layer, the substrate has a first surface facing the device sheet, the recess is defined on the first surface and the first metal layer is disposed on a portion of the first surface outside the recess;
the device sheet includes a substrate, a structure layer and a second metal layer sequentially stacked, the structure layer includes a first portion, in which structures for achieving mechanical functionality are formed, located in the functional cavity and a second portion surrounding the first portion, and the second metal layer is located on the second portion;
each of the cap sheet and the device sheet includes at least one electrode, the cap sheet is bonded with the device sheet via the first metal layer and the second metal layer, and all electrodes are electrically connected via the first metal layer and the second metal layer bonded with each other;
the cap sheet further includes a ground structure on the portion of the first surface outside the recess, and disposed along perimeter of a bonding area where the first metal layer located.

2. The MEMS device according to claim 1, wherein the ground structure is disposed on both sides or either side of the bonding area.

3. The MEMS device according to claim 1, wherein the bonding area is ring-shaped, and the ground structure is disposed along one or both of an outer side and an inner side of the bonding area.

4. The MEMS device according to claim 3, wherein the ground structure is a complete loop trench, or is a single or multiple short trenches.

5. The MEMS device according to claim 1, wherein the first metal layer covers the ground structure either fully or partially.

6. A method for manufacturing the MEMS device according to claim 1, comprising:
forming the cap sheet;
forming the device sheet; and
bonding the cap sheet and the device sheet;
wherein forming the cap sheet includes:
providing a first substrate;
forming an oxide layer on a first surface of the first substrate;
patterning the oxide layer to form a grounding structure and to reserve targeted bonding area, the grounding structure being disposed along perimeter of the targeted bonding area;
forming a first metal layer over the oxide layer at the target bonding area and in the grounding structure; and
removing portions of the oxide layer and the first substrate to form the recess, so that the first metal layer and the grounding structure are disposed on the portion of the first surface outside the recess;
wherein forming the device sheet includes:
providing a second substrate; and
forming the structure layer and the second metal layer on the second substrate, so that the structure layer includes a first portion, in which structures for achieving mechanical functionality are formed, located in the functional cavity and a second portion surrounding the first portion, and the second metal layer is located on the second portion;
wherein bonding the cap sheet and the device sheet includes:
performing a bonding process on the first metal layer and the second metal layer, so that the cap sheet is bonded with the device sheet via the first metal layer and the second metal layer, and all electrodes are electrically connected via the first metal layer and the second metal layer bonded with each other.

7. The method according to claim 6, wherein patterning the oxide layer to form the grounding structure and to reserve the targeted bonding area includes disposing the ground structure on both sides or either side of the bonding area.

8. The method according to claim 6, wherein patterning the oxide layer to form the grounding structure and to reserve the targeted bonding area includes disposing the targeted bonding area as ring-shaped, and disposing the ground structure along one or both of an outer side and an inner side of the targeted bonding area.

9. The method according to claim 8, wherein patterning the oxide layer to form the grounding structure and to reserve the targeted bonding area includes disposing the ground structure as a complete loop trench, or as a single or multiple short trenches.

10. The hand-held device according to claim 6, wherein in performing a bonding process on the first metal layer and the second metal layer, the first metal layer is squeezed out to flow into the ground structure to make the first metal layer cover the ground structure either fully or partially.
